(19) United States
(12) Patent Application Publication
(10) Pub. No.: US 2026/0148934 A1
(43) Pub. Date: May 28, 2026

(54) Ru ETCHING INDUCED BY ELECTRON BEAM IRRADIATION AND REMOTE PLASMA

(71) Applicant: University of Maryland, College Park, College Park, MD (US)

(72) Inventors: Gottlieb S. Oehrlein, Clarksville, MD (US); Yudong Li, Fremont, CA (US); Michael Hinshelwood, College Park, MD (US)

(21) Appl. No.: 19/400,352

(22) Filed: Nov. 25, 2025

Related U.S. Application Data
(60) Provisional application No. 63/725,307, filed on Nov. 26, 2024.

(51) Int. Cl. H01J 37/317; H01J 37/32; H10P 50/26

(52) U.S. Cl. CPC H01J 37/3174; H01J 37/32357; H01J 37/32889; H10P 50/267; H01J 37/32678; H01J 2237/31772

(57) ABSTRACT

A system for etching a sample includes a vacuum chamber, an electron beam source, and a remote plasma source. The sample is simultaneously subjected to irradiation from the electron beam source and a reactive neutral flux from the remote plasma source to induce etching of a surface of the sample.

### CROSS-REFERENCE TO RELATED APPLICATIONS

This application claims the benefit of and priority to U. S. Provisional Patent Application No. 63/725,307 filed on November 26, 2024, the entire contents of which are incorporated by reference herein.

### TECHNICAL FIELD

The present disclosure generally relates to an etching process for microelectronics processing, specifically precise, low-damage, spatially localized, and selective etching of Ru.

### BACKGROUND

Unless otherwise indicated herein, the materials described in this section are not prior art to the claims herein and are not admitted as being prior art by inclusion in this section. The removal of metal films in a non-damaging way is often required in microelectronics processing. As semiconductor technology continues to scale down, the precise, low-damage, spatially localized, and selective etching of metal is vital. Ruthenium (Ru) has shown potential for applications in the microelectronics industry due to its unique physical and chemical properties. Ru can be readily etched by a direct plasma approach using O2 containing feed gas mixtures. The energetic ion bombardment to the surface in a conventional plasma approach may introduce damage to the substrate materials.

### SUMMARY

Existing challenges associated with the foregoing, as well as other challenges, are overcome by the presently disclosed Ru etching induced by electron beam irradiation and remote plasma. One embodiment of the present disclosure is a system for etching a sample that includes a vacuum chamber, an electron beam source, and a remote plasma source. The sample is simultaneously subjected to irradiation from the electron beam source and a reactive neutral flux from the remote plasma source to induce etching of a surface of the sample.

In aspects, the sample includes Ru.

In aspects, the remote plasma source is fed an Ar/O₂/Cl₂ feed gas.

In aspects, the feed gas is 10 sccm Ar, 1.5 sccm Cl₂, and 3.5 sccm O₂.

In aspects, the remote plasma source utilizes electron cyclotron wave resonance and includes a neutralization plate to remove charged species from the reactive neutral flux produced by the remote plasma.

In aspects, the remote plasma source power is one of 200 W, 400 W and 600 W.

In aspects, the electron beam source is an electron flood gun.

In aspects, the system further includes a differential pumping unit to evacuate the electron flood gun during operation.

In aspects, an energy of the irradiating electrons from the electron flood gun is 1 keV.

Another embodiment of the present disclosure includes a method for etching a sample. The method includes exposing the sample in a vacuum chamber to simultaneous irradiation from an electron beam source and a reactive neutral flux from a remote plasma source to induce etching of a surface of the sample.

In aspects, the method further includes controlling a power of the remote plasma source in the range from 50 W to 2000 W.

In aspects the method further includes passivating a surface of the sample by the remote plasma source prior to exposing the sample to the simultaneous irradiation from the electron beam source and the reactive neutral flux from the remote plasma source.

In aspects, the remote plasma source includes a neutralization plate, and the method further includes removing charged species from the reactive neutral flux produced by the remote plasma source by the neutralization plate prior to exposing the sample to the reactive neutral flux.

In aspects, the electron beam source is an electron flood gun, and the method further includes evacuating the electron flood gun during operation with a differential pumping unit.

In aspects, the method further includes controlling an energy of irradiating electrons from the flood gun in the range from 200 eV to 30 keV.

In aspects, the electron beam source is a focused electron beam source configured for localized interactions and an energy of the irradiating electrons produced by the electron beam source is in the range from 200 eV to 30 keV.

Another embodiment of the present disclosure is a system for etching a sample. The system includes a vacuum chamber, an electron flood gun, a differential pumping unit, and a remote plasma source. The remote plasma source utilizes electron cyclotron wave resonance and includes a neutralization plate to remove charged species from the reactive neutral flux generated so only reactive neutrals remain. The sample is simultaneously subjected to irradiation from the electron flood gun and the reactive neutrals from the remote plasma source to induce etching of a surface of the sample.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 illustrates an exemplary system that can be utilized to etch Ru by electron beam irradiation and remote plasma in accordance with the present disclosure;

FIG. 2a is a graph of Ru thickness evolution during separate or simultaneous electron beam and remote plasma exposures with Ar/O₂/Cl₂ or Ar/O₂ as the remote plasma source feed gas in accordance with the present disclosure;

FIG. 2b is a graph of Ru and Ta removal rate derived from different exposures in accordance with the present disclosure;

FIG. 3 is a graph of the impacts of electron emission current and remote plasma power on the Ru etching rate in accordance with the present disclosure;

FIG. 4 is a graph of the influence of electron emission current on the Ru etching rate at different O₂/Cl₂ flows in accordance with the present disclosure;

FIG. 5 is a graph of the influence of O₂ flow on the Ru etching reaction at different electron emission currents and Cl₂ flows in accordance with the present disclosure;.

FIG. 6 is a graph of the influence of Cl₂/O₂ ratio and electron emission current on the Ru etching reaction in accordance with the present disclosure;

FIG. 7a is a graph of the spatially-resolved X-ray Photoelectron Spectroscopy (XPS) measurements of the Cl 2p spectra of the Ru sample in accordance with the present disclosure;

FIG. 7b is a graph of the spatially-resolved XPS measurements of the O 1s spectra of the Ru sample in accordance with the present disclosure;

FIG. 7c is a graph of the spatial evolution of the Cl 2p-to-O 1s ratio and the (Cl-O)-to-(Cl-Ru) ratio in accordance with the present disclosure;

FIG. 8 is a graph of the Cl 2p spectra of an Ru sample exposed to simultaneous electron beam and remote plasma exposure and an Ru sample exposed to only electron beam exposure with unexcited gas in accordance with the present disclosure;

FIG. 9a is a graph of the Cl 2p spectra of the Ru sample exposed to electron beam and remote plasma irradiation with high or low O₂/Cl₂ flow at the simultaneous electron beam and remote plasma exposed area in accordance with the present disclosure;

FIG. 9b is a graph of the Cl 2p spectra of the Ru sample exposed to remote plasma irradiation only with high or low O₂/Cl₂ flow in accordance with the present disclosure;

FIG. 10 is a graph of the influence of Cl₂/O₂ ratio and electron beam presence on the loss rate of either Ru or total thickness (Ru plus RuOₓCl_{y}) in accordance with the present disclosure;

FIG. 11a is a graph of Ru and RuFₓO_{y} thickness evolution during exposure of Ru to remote plasma with Ar/CF₄/O₂ feed gas in accordance with the present disclosure;

FIG. 11b is a graph of Ru thickness evolution of fully or partially fluorinated Ru samples (pre-exposed to remote plasma with Ar/CF₄/O₂ feed gas for either 50 s or 100 s) during exposure to remote plasma with Ar/O₂/Cl₂ as the feed gas in accordance with the present disclosure; and

FIG. 12 is a graph of Ru thickness evolution of a fluorinated Ru sample (pre-exposed to remote plasma with Ar/CF₄/O₂ feed gas) during sequential exposure to either remote plasma or electron beam and remote plasma with either Ar/Cl₂/O₂ or Ar/O₂ as the feed gas source in accordance with the present disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

Ru may be readily etched in a highly controlled etching approach by a simultaneous exposure of an Ru surface to a combination of electron beam irradiation and remote plasma (EB and RP). Reactive neutrals may be generated by a remote plasma source (RPS) fed with a gas mixture. For the RPS, plasma-generated charges may be removed, and only reactive neutrals remain which may be transported to the surface of the Ru material to produce a remote plasma modified surface. The reactive neutrals from the excited feed gas may functionalize the Ru surface of the Ru material and electrons generated from an electron beam (EB) source may induce etching of the remote plasma modified surface.

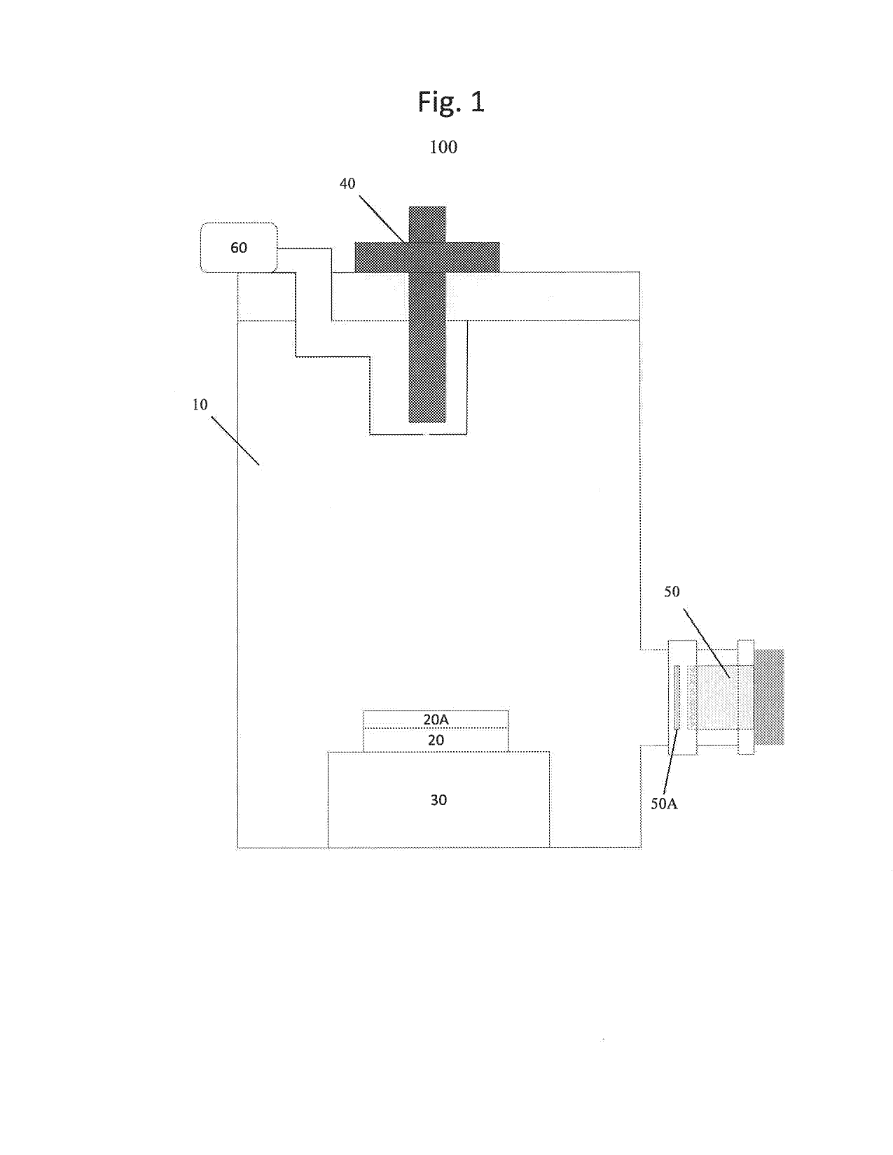

FIG. 1 illustrates an exemplary system that can be utilized to etch Ru by electron beam irradiation and remote plasma in accordance with at least some embodiments described herein. System 100 may include a vacuum chamber 10, an electron beam source 40, and a remote plasma source 50. Vacuum chamber 10 may further include a substrate support 30 supporting a substrate 20. Vacuum chamber 10 may be configured to produce a pressure within vacuum chamber 10 which is low enough to be compatible with the stability and operating characteristics requirements of electron beam source 40 when considering differential pumping. Vacuum chamber 10 may also provide gas throughput sufficient for high rate etching required when using remote plasma source 50.

The substrate (20) may include a ruthenium (Ru) film or a patterned Ru layer. Ru may have a lower bulk resistivity at tight pitch sizes and higher melting point than copper and may be utilized as an interconnect material. Ru may have a high resistance to corrosive environment and high transmissivity for extreme ultraviolet light at 13.5 nm wavelength. Ru may be used as a capping layer on extreme ultraviolet (EUV) photomasks to protect an underlying reflective silicon/molybdenum stack. The performance of an EUV photomask is quite sensitive to the properties of each component and a tiny thickness change or defect in the formation of a photomask may deteriorate the overall performance of the photomask. Substrate 20 may be any required substrate, including full size wafer.

Electron beam (EB) source 40 may be mounted on vacuum chamber 10 and may provide a focused electron beam which may be targeted towards substrate 20. EB source 40 may include electron optics and an electron scanning mechanism and vacuum generation capability. EB source 40 may be a focused electron beam source configured for localized interactions. An energy of the irradiating electrons produced by EB source 40 may be in the range from 200 eV to 30 keV. In an example, EB source 40 may be an electron flood gun, although other electron beam sources are contemplated. When EB source 40 is an electron flood gun, EB source 40 may require a lower vacuum to operate than can be produced by vacuum chamber 10, and system 100 may further include a differential pumping unit (DPU) 60 to evacuate EB source 40 during operation. When EB source 40 is an electron flood gun, the electron flood gun may be based on different sources including thermionic emission and field emission.

Remote plasma source 50 may be mounted on vacuum chamber 10 and may provide plasma to substrate 20. Remote plasma source 50 may provide a reactive species flux to substrate 20. Remote plasma source 50 may be any common remote plasma source including inductively coupled plasma or microwave plasma. Remote plasma source 50 may generate plasma by any conventional method including constant electric fields (DC), alternating electromagnetic fields (typically RF to GHz), and electron cyclotron wave resonance (EWCR). The properties of the plasma generated, such as particle temperature and density, may depend on the source used.

A surface 20A of substrate 20 may be functionalized or chemically activated by neutral species generated from remote plasma source 50. A power source for remote plasma source 50 may range from 50 W to 2000 W. Remote plasma source 50 may utilize a mixture of Ar/O₂/Cl₂ as a feed gas. In an embodiment, remote plasma source 50 may utilize electron cyclotron wave resonance (EWCR) with a neutralization plate 50A. Neutralization plate 50A may remove charged species and only permit neutral transport to be provided to substrate 20. Different remote plasma sources 50 are contemplated which may not require neutralization plate 50A to remove charged particles. Substrate 20 may be exposed to the effluent of remote plasma source 50 without ion bombardment due to neutralization plate 50A resulting in functionalized surface 20A. In an embodiment, remote plasma source 50 may passivate surface 20A prior to etching, such as by generating a 400W remote plasma with from a feed gas of 10 sccm Ar, 1 sccm O₂, and 4 sccm CF₄.

Substrate 20 may be simultaneously subjected to irradiation from EB source 40 and reactive species flux produced by remote plasma source 50. Surface 20A of substrate 20 may be functionalized or activated by neutral species generated from remote plasma source 50 with Ar/O₂/Cl₂ as the feed gas, and electron bombardment of the functionalized surface by EB source 40 may induce etching in surface 20A of substrate 20. Subjecting surface 20A simultaneously to electron beam irradiation from EB source 40 and reactive species flux produced by remote plasma source 50 may produce a synergistic effect in the etching of substrate 20 as compared to separate electron beam with Ar/O₂/Cl₂ gas mixture or Ar/O₂/Cl₂ remote plasma exposure by itself. Etching behavior of system 100 may be controlled and localized by control of electron beam irradiation from EB source 40. Cl₂ gas added to Ar/O₂ mixture may increase the etching response. The etching reaction may be adjusted by tuning the parameters of the EB source 40 and remote plasma source 50, including gas composition. Substrate 20 may be etched to a desired thickness with a removal rate of up to 6 (Å/min) or more depending on electron beam source 40 and remote plasma source 50 parameters. System 100 may enable selective removal of a sample which includes Ru over tantalum (Ta). System 100 may be applied to processes where low-damage, precise, or selective etching of Ru is desired.

### Examples

The effect of Cl₂ on Ru etching behavior and the synergistic effect of electron beam and remote plasma irradiation in the presence of oxygen and chlorine reactants was evaluated. A sequential processing involving either separate or simultaneous electron beam and remote plasma exposures with Ar/O₂/Cl₂ or Ar/O₂ as the remote plasma feed gas was applied to the Ru sample. The measured etching/deposition results of Ru were evaluated by ellipsometry, an optical method, in real time. The remote plasma source 50 feed gas was 10 sccm Ar and 5 sccm O₂ for Ar/O₂ configuration and 10 sccm Ar, 1.5 sccm Cl₂, 3.5 sccm O₂ for Ar/O₂/Cl₂ configuration (30% Cl₂). The power for remote plasma source 50 was 400 W, electron beam source 40 current was 0.1 mA with 1 keV electron energy, however, the parameters are not limited to these values.

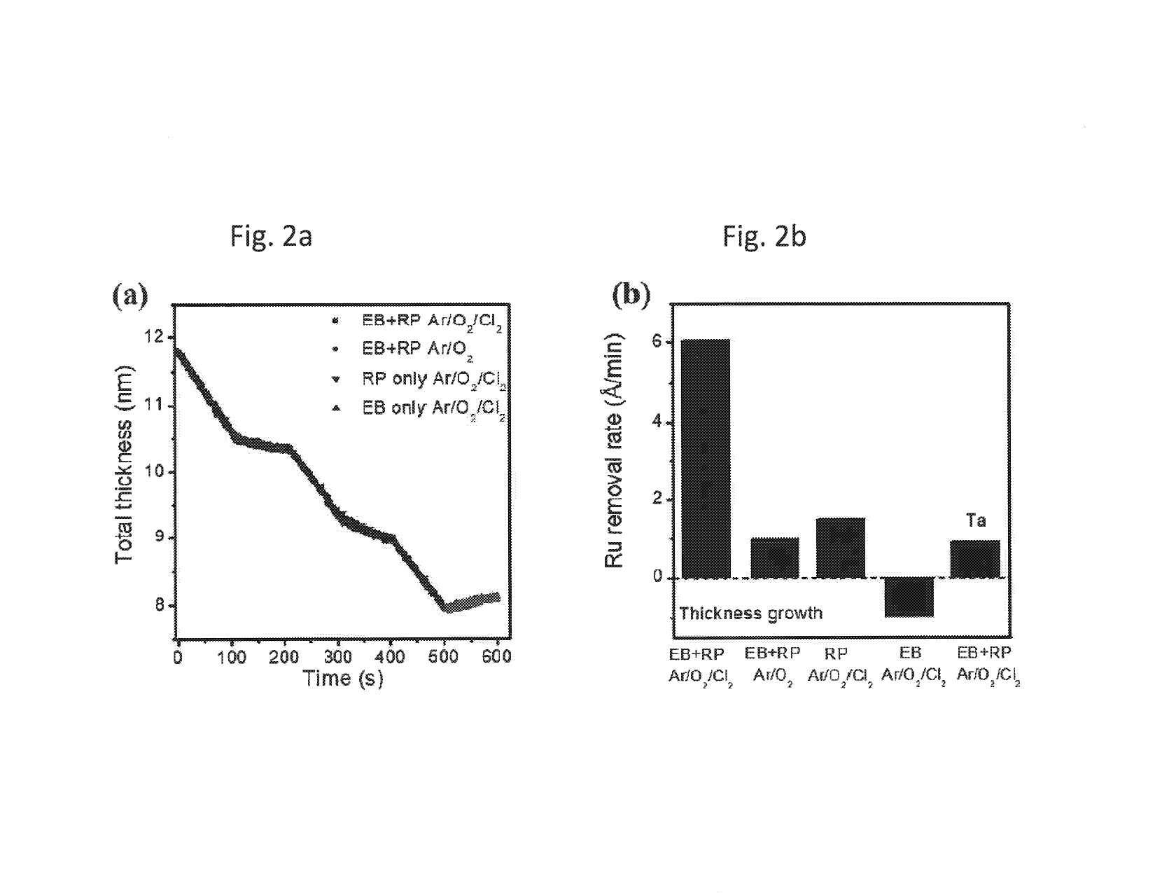

FIG. 2a is a graph of Ru thickness evolution during separate or simultaneous electron beam and remote plasma exposures with Ar/O₂/Cl₂ or Ar/O₂ as the remote plasma source feed gas and FIG. 2b is a graph of Ru and Ta removal rate derived from different exposures in accordance with at least some embodiments described herein. As shown in FIG. 2a, simultaneous electron beam and remote plasma exposure with Ar/O₂/Cl₂ as the remote plasma source 50 feed gas induces continuous Ru etching with a fast etching reaction (ER). If using Ar/O₂ gas as the remote plasma feed gas, the Ru removal rate is much smaller. The reactive species flux from a remote plasma source 50 fed with Ar/O₂/Cl₂ induces slow Ru etching without electron flux compared to exposure to fluxes from both the EB source 40 and remote plasma source 50. This result indicates that the Cl₂ addition to the Ar/O₂ gas mixture can greatly enhance Ru etching. The O-based or Cl-based neutrals generated from the remote plasma irradiation can functionalize the Ru, and the electron flux is able to promote desorption of the modified surface and enhance the etching of Ru. The Ru sample exposed to the electron flux with unexcited Ar/O₂/Cl₂ gas results in thin film thickness increase, likely due to the formation of non-volatile RuOₓCl_{y}. Without the plasma discharge, only a small number of reactive species can be generated, e.g., through electron beam-induced dissociation of the O₂ and Cl₂ gases. Those electron beam-generated species are insufficient to induce complete oxidation of the Ru required for formation of volatile Ru species, e.g., RuO₄ or RuOₓCl_{y} with a higher O stoichiometry and only non-volatile RuO₂ or RuOₓCl_{y} are formed, leading to the thickness growth. Those results signify the importance of the reactive neutrals in the etching of Ru.

The same simultaneous electron beam and remote plasma exposure with Ar/O₂/Cl₂ was applied on a Ta sample. The Ta sample underwent a slow oxidation reaction to form non-volatile Ta oxide. The thickness loss rate of the Ta sample due to oxidation was calculated and compared with the Ru etching reaction, as shown in FIG. 2b. The Ru etching reaction is much higher than the Ta loss rate, and a selectivity of 6 can be realized. The Ta metal loss rate will drop as the Ta surface continues to be oxidized, owing to the non-volatile Ta oxide layer serving as an inhibiting layer to impede the penetration of the electrons, thus a higher Ru over Ta selectivity can be realized.

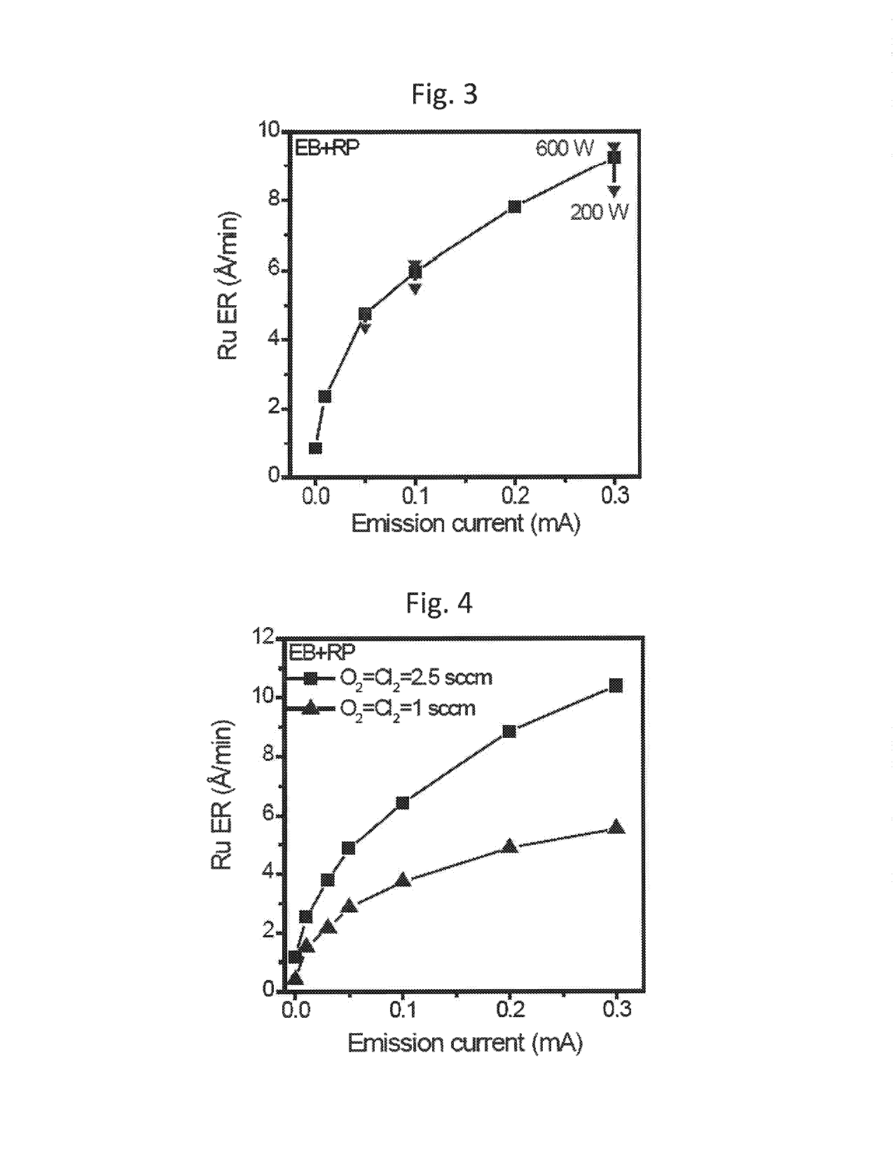

FIG. 3 is a graph of the impacts of electron emission current and remote plasma power on the Ru etching rate. The area of the sample irradiated by the electron beam depends on the electron beam energy and is fixed. As the electron emission current goes up, the current density (number of electrons per unit area and time) increases. The remote plasma source 50 feed gas was again 10 sccm Ar, 1.5 sccm Cl₂ and 3.5 sccm O₂ (30% Cl₂). Three remote plasma source 50 powers of 200 W, 400 W and 600 W were used, and the energy of the electrons was 1 keV. Other parameters may also be used. The electron flux to the sample is directly proportional to the electric current. Higher electron emission current provides more electron flux to the surface which promotes the desorption of oxidized Ru species and subsequently improves the Ru etching reaction. The change of Ru etching reaction with respect to electron emission current is more drastic at small electron emission current, and the impact of electron emission current gradually decreases as the electron emission current is raised. At higher electron emission current, the etching reaction is mostly limited by the neutral flux. Further increasing the electron emission current cannot enhance the etching reaction as much as at low electron emission current since volatile Ru species are desorbed faster than the Cl and O surface coverage can be replenished.

Three remote plasma source 50 powers at different electron emission current were also examined. The change of remote plasma source 50 power is associated with the variations of the reactive neutral fluxes to the Ru surface. Higher remote plasma source 50 power increases the dissociation of the O₂/Cl₂ gases and forms more reactive neutrals, which subsequently enhances the Ru etching and increases the Ru etching reaction. The etching reaction dependence on remote plasma source 50 power is more pronounced at larger electron emission current. Larger electron emission current variation from 200 W to 600 W can be seen at 0.3 mA than at 0.1 mA and 0.05 mA electron emission current. At lower electron emission current, the reaction is limited by the electron flux which limits the desorption of the volatile Ru products, and the impact of increasing remote plasma source 50 power will be lessened. The results in FIG. 3 indicate that etching reactions change from electron-flux limited at low electron emission current to a neutral-flux limited at high electron emission current.

FIG. 4 is a graph of the influence of electron emission current on the Ru etching rate at different O₂/Cl₂ flows. In FIG. 4, the ratio of the O₂ and Cl₂ flow was kept at 1 while their total flow was changed. Two Cl₂/O₂ flows, i.e., 1 sccm and 2.5 sccm, were applied. Ar gas was injected to maintain a total flow of 15 sccm. Remote plasma source 50 power used was 400 W. 1 keV electron energy was used. Electron emission current was varied at different O₂/Cl₂ flows to investigate the electron-flux dependence of the etching reaction. The etching reaction at two different flows share a similar trend as shown in FIG. 3. As previously shown, the etching reaction increases faster with electron emission current at low electron emission current and the etching reaction increase slows down at higher electron emission current, indicating that the Ru etching reaction is restrained by the electron flux at low electron emission current and limited by the neutral flux at high electron emission current. The etching reaction with Cl₂/O₂ flow of 2.5 sccm is higher than that of 1 sccm, due to more reactive neutrals being available for 2.5 sccm gas flow rate. The Ru etching reaction increase vs. electron emission current is also higher for larger Cl₂/O₂ flows. With a lower Cl₂/O₂ flow, less reactive neutrals were generated, and the Ru etching reactions are limited by the neutral flux.

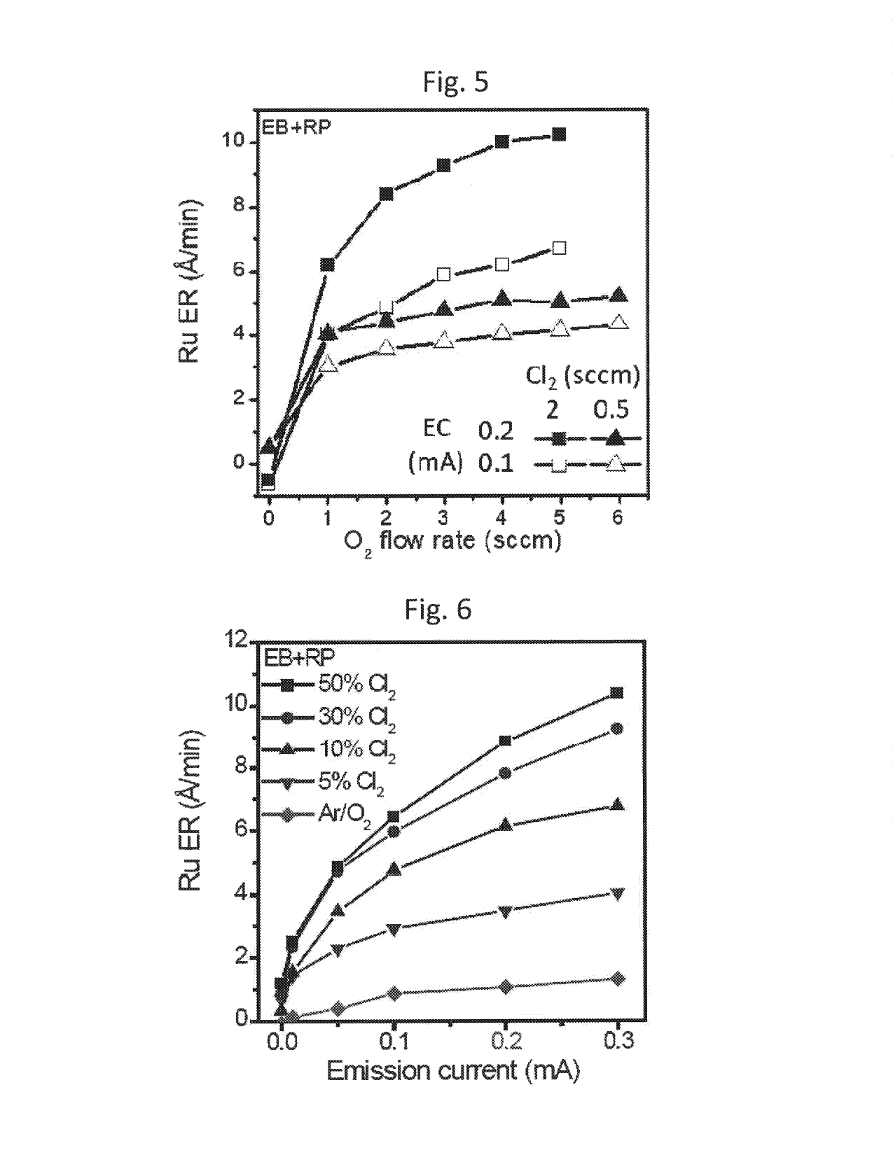

FIG. 5 is a graph of the influence of O₂ flow on the Ru etching reaction at different electron emission currents and Cl₂. O₂ flow rate was varied for two different Cl₂ flow rates (2 sccm or 0.5 sccm) and electron emission currents (0.1 mA and 0.2 mA), representing high and low Cl-based neutral and electron fluxes, as shown in FIG. 5. 8 sccm Ar was also injected to remote plasma source 50 with a power of 400 W. 1 keV electron energy was used. In general, Ru etching reaction increases with O₂ and Cl₂ flows and electron emission current. Higher Cl₂ or O₂ flow to the remote plasma source 50 generates more O- and Cl-based neutrals, which diffuse to the Ru surface and promote the functionalization and activation of the Ru surface. Higher electron emission current provides higher electron flux to the surface to promote the desorption of the activated Ru surface, which subsequently enhances the Ru etching reaction. The increase of etching reaction is sharper with smaller O₂ flow than for higher O₂ flow, since the etching transfers from an O neutral-limited reaction to a reaction limited by other aspects, such as the Cl neutrals or electron flux. A sharper etching reaction increase with O₂ flow is observed for a higher Cl₂ flow or a higher electron emission current, since the Cl-based neutrals and the electron flux are not limiting the etching reaction as much as that with the lower Cl₂ flow and electron emission current. It is worth noting that rather than Ru etching, formation of Ru chloride or oxychloride is observed for all four experiments at 0 sccm O₂ flow. The material growth rate at 0 sccm O₂ is clearly larger for high Cl₂ flow rates. For low Cl₂ flow rates, slight material growth is still seen.

FIG. 6 is a graph of the influence of Cl₂/O₂ ratio and electron emission current on the Ru etching reaction. The individual effects of Cl₂ and O₂ flow and their reactive neutrals were evaluated. The total flow of Cl₂ and O₂ was fixed and the individual flows were varied (increasing the Cl₂ flow decreases the O₂ flow). As shown in FIG. 6, the Ru etching reaction as a function of electron emission current with different Cl₂ concentrations were analyzed. The total flow of O₂ and Cl₂ was fixed at 5 sccm. The remote plasma source 50 feed gas was 10 sccm Ar and 5 sccm of O2/Cl2. Remote plasma source 50 power was 400 W. 1 keV electron energy was used. Similarly, the Ru etching reaction increased with electron emission current for all gas flows. The etching reaction also increases sharply at small electron emission current and more slowly at large electron emission current for a given flow composition. The Ru etching reaction monotonically increases with Cl₂ concentration, even though the O₂ concentration decreases. 10-20% Cl₂ addition to the O₂ generates the highest reactive oxygen density. The monotonic increase of the etching reaction to Cl₂ concentration rather than the density of reactive O species indicates that the Cl₂ addition does not just play a role in the gas phase reaction. For low Cl₂ flow, etching reaction almost levels off at high electron emission current, especially for the Ar/O₂ case without Cl₂ flow. For high Cl₂ flow, the influence of electron emission current is still quite pronounced at high electron emission current, reflected by the fast increase of etching reaction with electron emission current. This observation indicates that the reaction is being restricted by Cl-based neutrals incident to the surface. Due to the insufficient supply of Cl-based species, the etching reaction is restrained and cannot respond effectively to the large incident O-based neutrals and electron fluxes. These results indicate that the Cl-based species directly participate in the surface reactions with Ru and promote the etching.

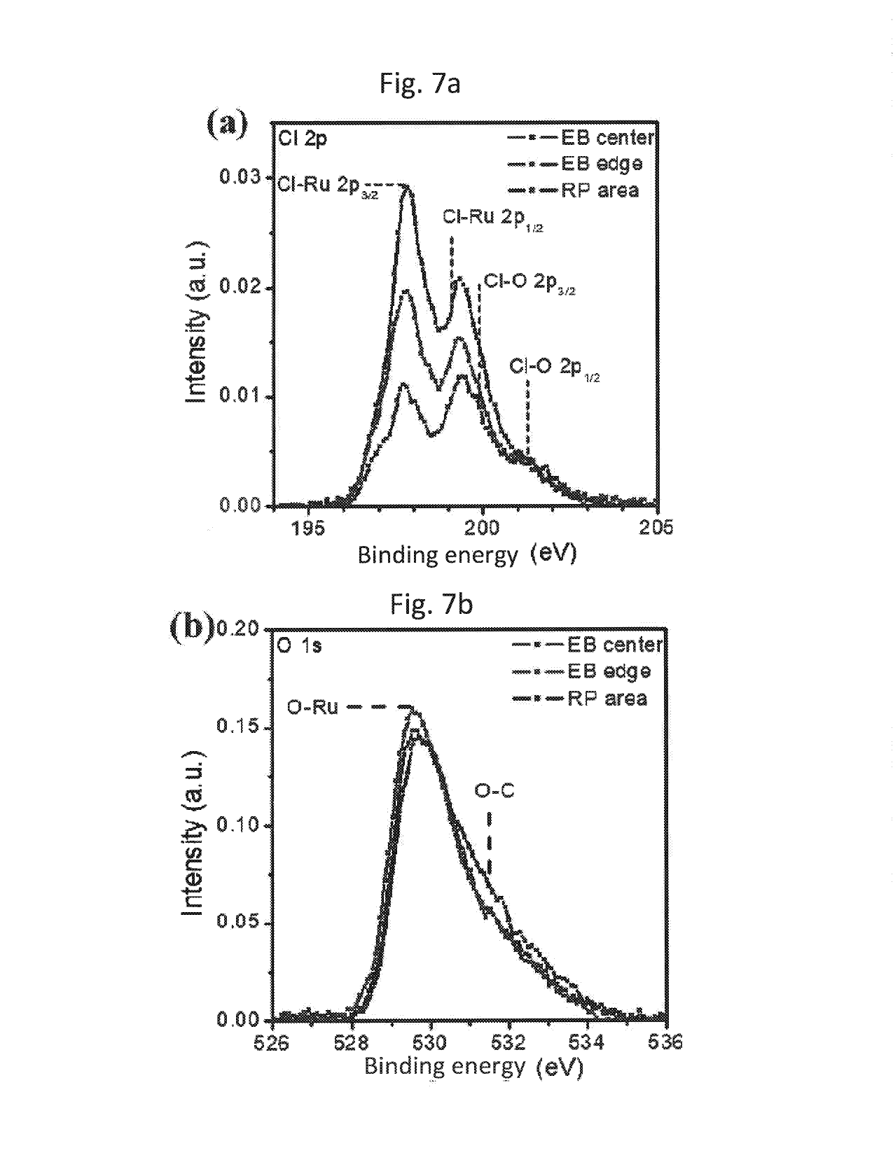

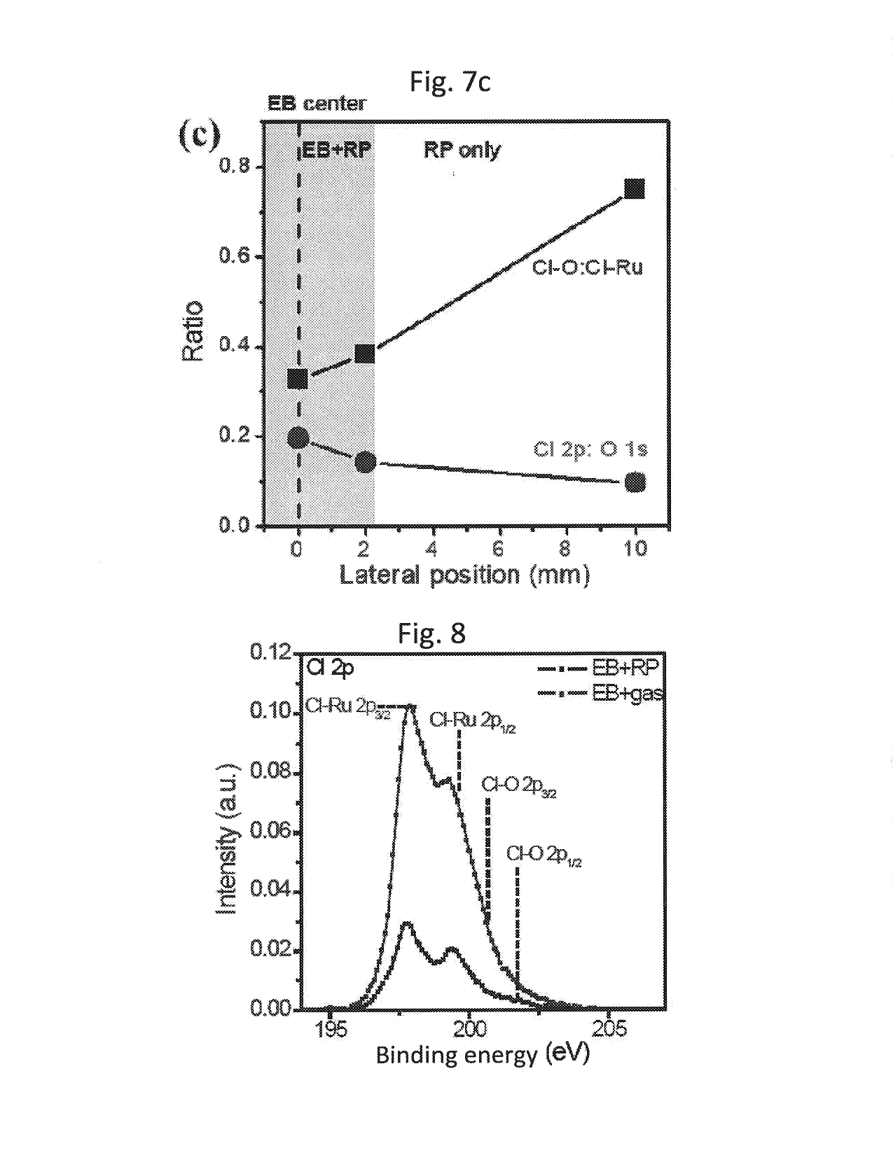

FIG. 7a is a graph of the spatially-resolved XPS measurements of the Cl 2p spectra of the Ru sample, FIG. 7b is a graph of the spatially-resolved XPS measurements of the O 1s spectra of the Ru sample, and FIG. 7c is a graph of the spatial evolution of the Cl-to-O ratio and the (Cl-O)-to-(Cl-Ru) ratio. A sample was prepared by exposure to 400 W remote plasma with 10 sccm Ar, 2.5 sccm O₂ and 2.5 sccm Cl₂ and electron beam with 0.3 mA EC and 1 keV electron energy. The focused electron beam irradiation from the flood gun was only applied to a small portion on the Ru sample, spatially-resolved XPS was done at three locations to give spatially-resolved surface chemistry information: one location at the center of the electron beam exposed area, one location at the edge of the electron beam exposed area and one location in the remote plasma only exposed area. With remote plasma only exposure, surface Cl and O were detected by XPS, indicating that the remote plasma can functionalize or activate the surface Ru through chlorination and oxidation. Cl 2p spectra shows a large increase of the Cl intensity moving towards the simultaneous electron beam and remote plasma exposed area, as shown in FIG. 7a and FIG. 7c. This is consistent with the Ru etching reaction which is higher with concurrent electron beam and remote plasma exposure than the remote plasma only exposure. The electron incident on the Ru can likely promote the formation of dangling bonds (DB) among Ru atoms, which become more reactive and subsequently react with and promote the adsorption of Cl and O neutrals. The Cl-based neutrals might promote the desorption of the modified Ru surface. However, the relative concentration of the Cl-O to the Cl-Ru becomes less, which is shown in FIG. 7c. This is likely ascribed to the more pronounced effect of ClO species in the enhancement of the Ru etching, which are removed in a faster manner with Ru than Cl bonded to Ru. The spatial difference of the O 1s spectra is more difficult to interpret, with potentially more O on the edge of the electron beam exposed area, but fewer in the electron beam center. This can be explained by the differing Ru etching reaction with respect to the surface O concentration. Since Ru oxychloride with higher O concentration is more volatile, O species may be more often taken up in volatile compounds which leave the surface, resulting in a lower surface O coverage.

FIG. 8 is a graph of the Cl 2p spectra of an Ru sample exposed to simultaneous electron beam and remote plasma exposure and an Ru sample exposed to only electron beam exposure with unexcited 10 sccm Ar, 2.5 sccm O₂/Cl₂ gas. In FIG. 2a and FIG. 2b, concurrent electron beam and remote plasma exposure induced Ru etching, and electron beam only exposured the sample with unexcited Cl₂ and O₂ gases resulted in thickness increase, likely due to the formation of non-volatile Ru oxychloride. XPS were performed on samples exposed to concurrent electron beam and remote plasma irradiation or electron beam only irradiation with unexcited Ar/O₂/Cl₂, and the comparison of the XPS spectra is shown in FIG. 8. The samples were prepared by either exposing to simultaneous remote plasma with 400 W and 10 sccm Ar, 2.5 sccm O₂/Cl₂ and electron beam with 0.3 mA electron emission current or exposing to electron beam with 0.3 mA electron emission current only with unexcited Ar/O₂/Cl₂ gases. Both cases used 1k eV electron energy. A great amount of Cl 2p uptake is observed for electron beam only exposure compared to concurrent electron beam and remote plasma exposure, indicating that Ru underwent a strong chlorination reaction. This is consistent with our in-situ ellipsometry measurement in FIG. 2 that electron beam only exposure promotes the formation of a highly chlorinated Ru layer, which stays on the surface. Electron beam can dissociate the O₂ and Cl₂ gases to some extent and produce reactive species through electron collisions with the gas molecules. With a lower dissociation energy of Cl₂ than that of O₂, electron beam is relatively more effective at dissociating Cl₂ than O₂, resulting in more reactive Cl-based species residing on Ru. As mentioned above, a substrate exposed to an energetic electron flux can likely form dangling bonds by electronic excitation. The Cl species can continue to react with the activated Ru by diffusing through the surface layer. Due to the lack of a reactive flux from the remote plasma source 50, the reactive O species generated in this mode of operation by the electron beam are not sufficient to oxidize the Ru to form a volatile Ru compound. The non-volatile Ru oxychloride accumulates on the surface, which explains the thickness increase observed in FIG. 2 with electron beam irradiation only.

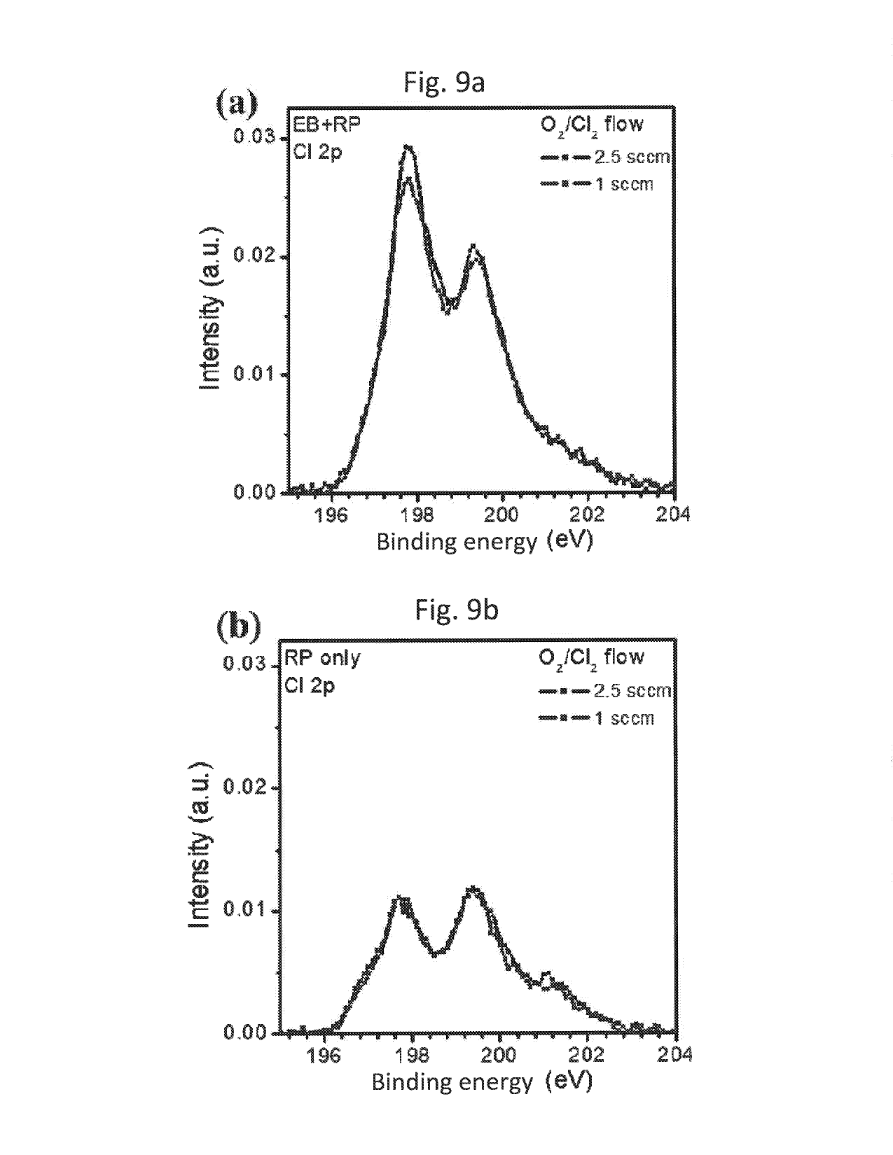

FIG. 9a is a graph of the Cl 2p spectra of the Ru sample exposed to electron beam and remote plasma irradiation with high or low Cl₂/O₂ flow at the simultaneous electron beam and remote plasma exposed area and FIG. 9b is a graph of the Cl 2p spectra of the Ru sample exposed to electron beam and remote plasma irradiation with high or low Cl₂/O₂ flow at the remote plasma only exposed area. The Cl 2p spectra of the Ru samples exposed to high and low neutral fluxes with simultaneous electron beam and remote plasma exposure, as described in FIG. 4, or remote plasma only exposure are shown in FIG. 9a and FIG. 9b, respectively. 400 W remote plasma and 0.3 mA electron beam with 1k eV electron energy were used, and 2.5 sccm or 1 sccm O₂/Cl₂ gases were injected to remote plasma source 50. Additional Ar flow was applied to maintain a total flow of 15 sccm. Higher surface Cl coverage is observed on Ru exposed to both electron beam and remote plasma irradiation with higher neutral flux, as shown in FIG. 9a and FIG. 9b. More Cl-based species are available from remote plasma source 50 with higher gas flow, resulting in more surface coverage during steady-state etching. The surface coverage of Cl on the sample exposed to remote plasma only irradiation does not show an obvious difference with high and low Cl₂/O₂ flow, as shown in FIG. 9b. Since the etching reaction triggered by the remote plasma only exposure is so slow, the surface tends to be more stable instead of being in dynamic equilibrium. Once the neutrals fill up the available surface sites and without the electron beam to drive the further etching, no more neutrals can be adsorbed due to surface saturation.

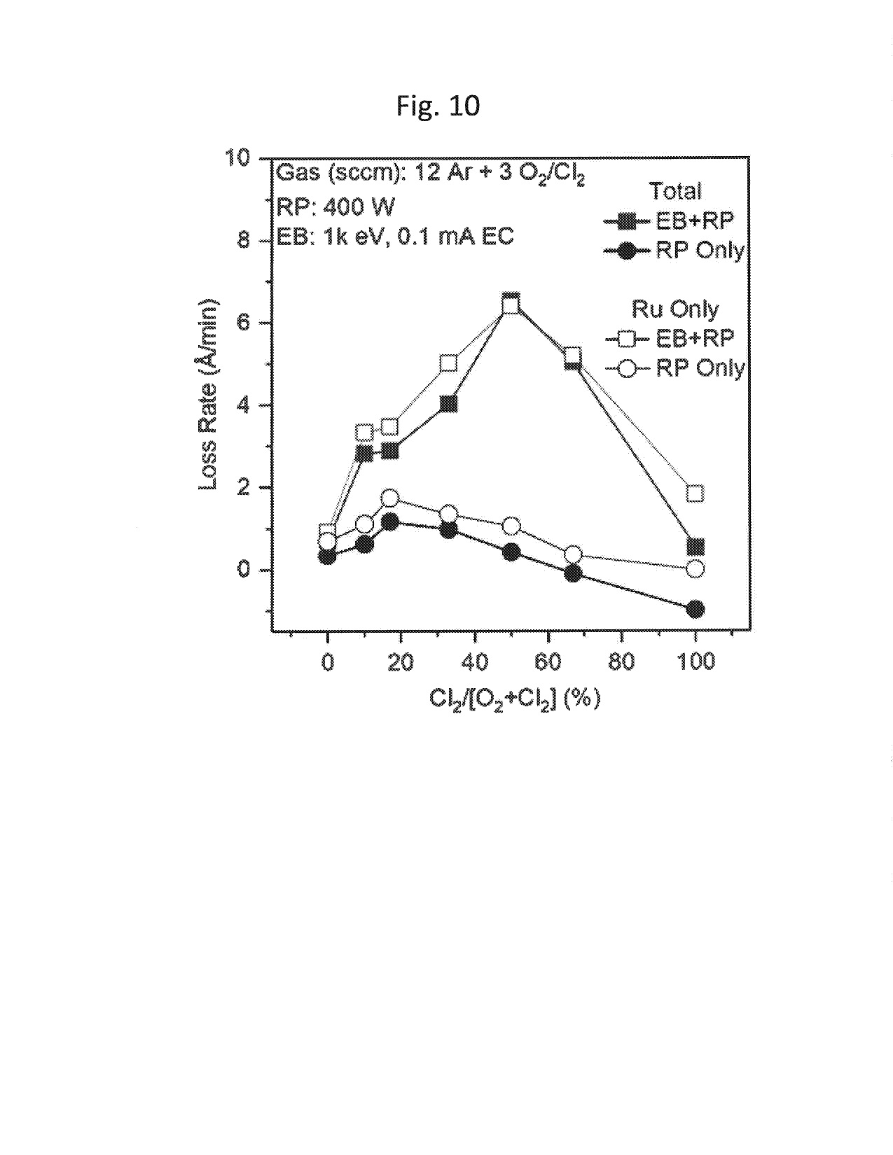

FIG. 10 is a graph of the influence of Cl₂ to O₂ ratio on the etching rate for the full range of 0 to 100% Cl₂ for remote plasma only or electron beam and remote plasma. The remote plasma source in this experiment was maintained at 400 W with a feed gas of 12 sccm Ar and 3 sccm total Cl₂/O₂. For the electron beam and remote plasma case, the electron beam was run at 1 k eV and 0.1 mA. Both the Ru loss rate and the total material loss rate are shown. The total material loss rate was based on the total material thickness, including Ru and RuOₓCl_{y}. The removal rates differ if Ru is lost to non-volatile RuOₓCl_{y} formation, rather than etched away. FIG. 10 shows that for the remote plasma only condition, both the total and Ru loss rates are maximum at 20% Cl₂. Meanwhile for combined electron beam and remote plasma exposure, total and Ru loss rates are maximum at 50% Cl₂ and the loss rate remains elevated at even higher Cl₂ percentages. Based on FIG. 10, at 20% Cl₂ the Ru loss selectivity to the electron beam spot is only 2. At 50%, the Ru loss selectivity to the electron beam spot is 6 and at 70% Cl₂ the selectivity is 4.5. Selectivity to etching at the electron beam spot is achieved both by increasing the etch rate, and also by changing the feed gas conditions where the maximum etch rate is achieved. Both the etch rate and selectivity may be increased even further by increasing electron flux. As shown, high etch selectivity to an exposed area may be achieved without sacrificing overall etch rate.

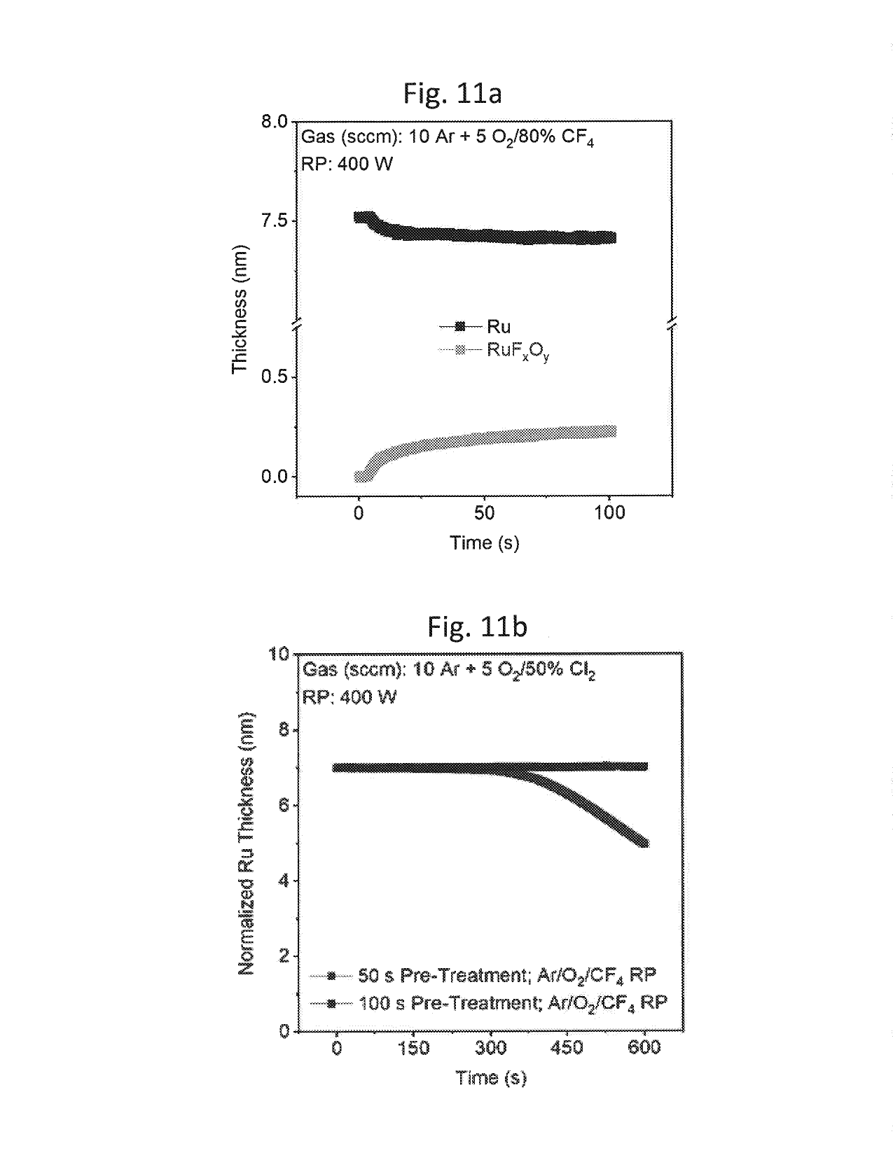

For non-electron beam exposed surface, etching proceeds via the adsorption of Cl₂/O₂ generated radicals on the Ru surface. Adsorption of Cl and ClO in particular, are known to activate the surface Ru towards formation of volatile compounds. In some processes, there is a need to completely limit the Ru removal to an area exposed to the electron beam. Selectivity is already present, as was shown in FIG. 10. However, selectivity may be improved by passivating the surface to radical-only induced formation of volatile species. Fluorine (F) will interact with Ru; however it does not enhance the formation of volatile Ru oxides like Cl or ClO. FIG. 11a shows the growth of RuFₓO_{y} during 100 seconds of Ru exposure to 400W remote plasma with a feed gas of 10 sccm Ar, 1 sccm O₂, and 4 sccm CF₄. 80% CF₄ is known to maximize the production of F in the plasma. Less than 0.25 nm of RuFₓO_{y} grew and Ru loss was minimal, with the growth rate slowing down over time. This fluorinated surface was then exposed to 600 s of 400 W remote plasma with 10 sccm Ar and 2.5 sccm of both O₂ and Cl₂. FIG. 11b shows the thickness of Ru over the exposure time, for a sample that was exposed to either 50 s of CF₄/O₂ plasma (less fluorination) or 100 s (more fluorination). In both cases, the Ru surface was initially unchanged. However, for the less fluorinated case, the surface is eventually etched. The more fluorinated surface was passivated for the entire 600 s exposure remote plasma.

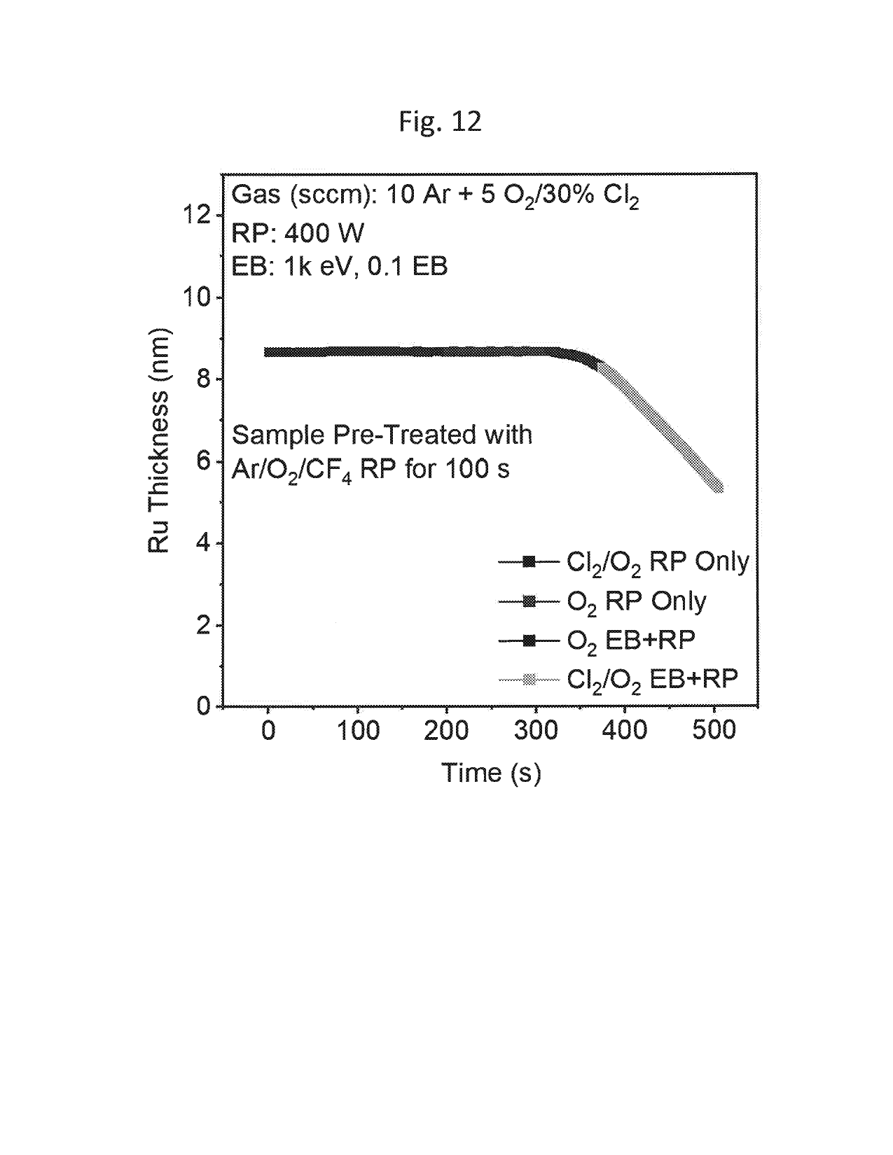

FIG. 12 demonstrates the effect of fluorine-based passivation on subsequent etching with both electron beam and remote plasma. In this sequential experiment, the Ru surface was first passivated with 100 s of 400 W Ar/CF₄/O₂ plasma. The passivated surface was then exposed to 400 W Ar/Cl₂/O₂ remote plasma for 200 s, then 400 W Ar/O₂ remote plasma for 100 s. Across both of these exposures the Ru was unetched. When the electron beam was subsequently turned on at 1k eV and 0.1 mA, the RuFₓO_{y} surface was removed and etching of the Ru surface began for the combined (EB+RP) exposure. The last step, introduction of Cl₂ to the remote plasma, further increased the etch rate for the (EB+RP) exposure. These results indicate that the electron beam can induce etching in surfaces that are passivated to remote plasma formed reactive species.

Through the use of CF₄ remote plasma pre-treatment, the Ru surface can be passivated against etching by reactive species formed by Ar/Cl₂/O₂ remote plasma. The electron beam can overcome the passivation and allow etching to occur. Thus, very high etch selectivity to the electron beam exposure spot can be achieved on a Ru surface. The amount of fluorination can be tailored by changing the remote plasma source power, feed gas, or exposure time, depending on the degree of passivation required for the subsequent etch step.

In embodiments, etch selectivity to the specific area of the electron beam exposed area, may be accomplished by the system. Combined electron beam and remote plasma not only boost the etch rate vs only remote plasma, but also shift the gas flow conditions for the maximum etch rate, which provides more opportunity to achieve high selectivity without sacrificing etch rate.

The interaction of Ru with electron beam and Cl₂ gas provides another variable by which the process may be controlled. Exposure of Ru to electron beam and Cl₂ gas results in the formation of a reactive Ru-Cl layer. This Ru-Cl layer is etched more readily than bulk Ru, including by just reactive oxygen species which would otherwise form non-volatile RuO₂. This makes Cl₂ concentration in the reaction chamber an important variable for the etch process.

In another embodiment, a passivation mechanism is described, by which etch selectivity to the electron beam exposed area may be improved. Exposure of the Ru surface to F, derived from CF₄/O₂ plasma, results in the formation of an RuFₓO_{y} layer as F adsorbs on the Ru surface. Ar/Cl₂/O₂ remote plasma does not etch this layer without the presence of the electron beam. Thus, etching of Ru is prevented until the passivated surface is exposed to the electron beam, which forms vacancies on which Cl and O can absorb. A system in accordance with the present disclosure may provide precise and damage-free etching of Ru samples by simultaneous exposure to electron beam and remote plasma. A system in accordance with the present disclosure may provide precise and damage-free etching of Ru samples by functionalizing the Ru surface with O- and Cl based neutral species generated from the remote plasma and electrons from the electron beam may deliver energy to the sample surface to promote etching. A system in accordance with the present disclosure may reduce surface damage to the sample during the etching process by removing ions from the remote plasma to mitigate ion bombardment during the etching process. A system in accordance with the present disclosure may provide for the patterning of Ru-based interconnects and barrier layers. A system in accordance with the present disclosure may provide for the selective removal of Ru over Ta extreme ultraviolet (EUV) photomask cleaning.

Finally, the processes and techniques described herein are not inherently related to any apparatus and may be implemented by any suitable combination of components. Further, various types of general-purpose devices may be used in accordance with the teachings described herein. It may also prove advantageous to construct specialized apparatus to perform the method steps described herein. This disclosure has been described in relation to the examples, which are intended in all respects to be illustrative rather than restrictive.

The foregoing description is only illustrative of the present disclosure. Various alternatives and modifications can be devised by those skilled in the art without departing from the disclosure. Accordingly, the present disclosure is intended to embrace all such alternatives, modifications, and variances. The embodiments described with reference to the attached drawing figures are presented only to demonstrate certain examples of the disclosure. Other elements, steps, methods, and techniques that are insubstantially different from those described above and/or in the appended claims are also intended to be within the scope of the disclosure.

What is claimed is:

1. A system for etching a sample comprising:
a vacuum chamber;
an electron beam source; and
a remote plasma source;
wherein the sample is simultaneously subjected to irradiation from the electron beam source and a reactive neutral flux from the remote plasma source to induce etching of a surface of the sample.

2. The system of claim 1, wherein the sample includes Ru.

3. The system of claim 1, wherein the remote plasma source is fed Ar/O₂/Cl₂ feed gas.

4. The system of claim 1, wherein the remote plasma source passivates the surface of the sample prior to etching the sample.

5. The system of claim 1, wherein the remote plasma source utilizes electron cyclotron wave resonance and includes a neutralization plate to remove charged species from the reactive neutral flux produced by the remote plasma.

6. The system of claim 1, wherein the remote plasma source power is one of 200 W, 400 W and 600 W.

7. The system of claim 1, wherein the electron beam source is an electron flood gun.

8. The system of claim 7, further comprising a differential pumping unit to evacuate the electron flood gun during operation.

9. The system of claim 7, wherein an energy of the irradiating electrons from the electron flood gun is in the range from 200 eV to 30 keV.

10. A method for etching a sample, the method comprising:
exposing the sample in a vacuum chamber to simultaneous irradiation from an electron beam source and a reactive neutral flux from a remote plasma source to induce etching of a surface of the sample.

11. The method of claim 10, wherein the sample includes Ru.

12. The method of claim 10, further comprising controlling a power of the remote plasma source in the range from 50 W to 2000 W.

13. The method of claim 10, wherein the remote plasma source has an Ar/O₂/Cl₂ feed gas.

14. The method of claim 10, further comprising passivating a surface of the sample by the remote plasma source prior to exposing the sample to the simultaneous irradiation from the electron beam source and the reactive neutral flux from the remote plasma source.

15. The method of claim 10, wherein the remote plasma source includes a neutralization plate, and the method further comprises removing charged species from the reactive neutral flux produced by the remote plasma source by the neutralization plate prior to exposing the sample to the reactive neutral flux.

16. The method of claim 10, wherein the electron beam source is an electron flood gun, the method further comprising evacuating the electron flood gun during operation with a differential pumping unit.

17. The method of claim 16, further comprising controlling an energy of the irradiation from the flood gun in the range from 200 eV to 30 keV.

18. The method of claim 10, wherein the electron beam source is a focused electron beam source configured for localized interactions and an energy of the irradiating electrons produced by the electron beam source is in the range from 200 eV to 30 keV.

19. A system for etching a sample comprising:
a vacuum chamber;
an electron flood gun;
a differential pumping unit; and
a remote plasma source which utilizes electron cyclotron wave resonance and includes a neutralization plate to remove charged species from a reactive neutral flux generated by remote plasma, so only reactive neutrals remain;
wherein the sample is simultaneously subjected to irradiation from the electron flood gun and the reactive neutrals from the remote plasma source to induce etching of a surface of the sample.

20. The system of claim 19, wherein the sample includes Ru.
